(19) United States
(12) Patent Application Publication
(10) Pub. No.: US 2007/0012983 A1
(43) Pub. Date: Jan. 18, 2007

(54) Terminations for semiconductor devices with floating vertical series capacitive structures

(76) Inventors: Robert Kuo-Chang Yang, San Jose, CA (US); Richard A. Blanchard, Los Altos, CA (US); Francois Hebert, San Mateo, CA (US)

Correspondence Address: LUMEN INTELLECTUAL PROPERTY SERVICES, INC., 2345 YALE STREET, 2ND FLOOR, PALO ALTO, CA, 94306, US

(21) Appl. No.: 11/487,142

(22) Filed: Jul. 14, 2006

Related U.S. Application Data
(63) Continuation-in-part of application No. 11/202,523, filed on Aug. 11, 2005.
(60) Provisional application No. 60/699,448, filed on Jul. 15, 2005.

(51) Int. Cl. H01L 29/94

(52) U.S. Cl. 257/301; 257/E29.346

(57) ABSTRACT

This invention relates to achieving high breakdown voltage and low on-resistance in semiconductor devices that have top, intermediate and bottom regions with a controllable current path traversing any of these regions. The device has an insulating trench that is coextensive with the top and intermediate regions and girds these regions from at least one side and preferably from both or all sides. A series capacitive structure with a biased top element and a number of floating elements is disposed in the insulating trench, and the intermediate region is endowed with a capacitive property that is chosen to establish a capacitive interaction or coupling between the series capacitive structure and the intermediate region so that the breakdown voltage V_{BD} is maximized and on-resistance is minimized. A second series capacitive structure disposed in a second insulating trench can be employed to terminate the device.

### CROSS REFERENCE TO RELATED APPLICATIONS

This application is a continuation in part of U.S. application Ser. No. 11/202,523, filed on Aug. 11, 2005, and entitled “Increasing Breakdown Voltage in Semiconductor Devices with Vertical Series Capacitive Structures”. This application also claims the benefit of U.S. provisional application 60/699,448, filed on Jul. 15, 2005, entitled “Terminations for Semiconductor Devices with Floating Vertical Series Capacitive Structures”, and hereby incorporated by reference in its entirety.

### FIELD OF THE INVENTION

This invention relates generally to semiconductor devices and in particular to high-voltage semiconductor devices that need to exhibit high breakdown voltage and low on-resistance.

### BACKGROUND

Semiconductor devices are striving to achieve a high breakdown voltage as well as low on-resistance. This goal is particularly true of devices that operate at high voltages, such as high power devices. Breakdown is typically caused by concentration of electric fields within at device edges, corners and other points or junctions. High on-resistance is caused by unfavorable geometrical and material composition of the device, e.g., large form factors, use of high-resistivity materials and other measures that are typically required for high breakdown voltage. In fact, doubling the breakdown voltage of a semiconductor device typically requires as much as a five-fold increase in the on-resistance.

There are two general techniques for combating the problem of electric field concentration and low breakdown voltages in planar semiconductor devices. The first is planar edge termination technique and the second is beveled termination technique, especially well-suited for edges. Some specific examples are found in early planar devices, such as planar PN junctions, in which the need to achieve better surface breakdown was recognized, e.g., in U.S. Pat. No. 4,074,293 to Kravitz. The inventor of this patent notes that bulk breakdown level voltages are much higher than surface voltages, but are hard to achieve at the surface. The teachings of Kravitz further indicated that controlling the processing of the regions in terms of doping/diffusion can help in increasing the breakdown voltage and achieving low on-resistance. More recently, U.S. Pat. No. 4,816,882 to Blanchard et al. teaches the use of equipotential rings for limiting the electric field specifically in power devices such as metal-oxide-silicon (MOS) transistors.

High electric strength or high breakdown voltage along the surface of a semiconductor device continues to be achieved with the aid of surface structures including field plates and guard rings. For details on their more recent employment the reader is referred to U.S. Pat. No. 5,113,237. More recently still, the capacitive coupling effects between field plates have been expressly recognized and used to further improve breakdown performance. For example, U.S. Pat. Nos. 5,204,545 and 5,334,546 to Terashima teach the use of capacitively coupled field plates for better electric field control. The capacitance and in particular the capacitive coupling of the conductive plates and the p-type diffused regions are optimized by Terashima so that potentials of the conductive plates and the p-type diffused regions can change in a substantially linear fashion from a low level to a high level. Thus, the concentration of electric field lines—the mechanism leading to breakdown—can be-prevented. It should be noted, however, that the field “spreading” technique proposed by Terashima is a planar effect (or two-dimensional effect), where the electric field gets spread out along the junction surface.

In taking a somewhat different approach, U.S. Pat. Nos. 5,731,627 and 6,190,948 to Seok discuss the use of overlapping floating field plates on the surface of a semiconductor device. These plates are formed on an electrically insulating region and capacitively coupled in series between an active region of a power semiconductor and a floating field ring. This structure has been shown to increase the breakdown of the P-N junction. An electrically insulating region is provided on the face and a primary field plate is formed on an upper surface of the electrically insulating region. More recently still, terminations using plates and vertically positioned elements, sometimes referred to as posts, have been suggested in the prior art. Corresponding and related teachings can be found in U.S. Pat. Nos. 6,307,232, 6,603,176, and 6,724,066. Some of the vertical structures proposed for these high breakdown voltage semiconductor devices include plates, e.g., as described in U.S. Pat. No. 6,617,652, and U.S. Patent Applications 2001/0004124 and 2002/0135019. It should be observed, that the approach disclosed by these references uses means of achieving the theoretical 1D (one-dimensional) breakdown voltage limit by ensuring that there is no premature breakdown of a junction at its periphery or edges.

Another noteworthy development in ensuring high breakdown voltage capability under reverse voltages in semiconductor power devices is the “super-junction” concept. In accordance with this idea described by Chen in U.S. Pat. No. 5,216,275, two kinds of regions are alternatively used in a composite buffer layer to improve the relation between on-resistance and breakdown voltage. The art contains many additional contributions based on this technique. These contributions include materials for better operation and uniform electric field distribution along the length of the trench during blocking as taught, e.g., by U.S. Pat. No. 6,608,350 to Kinzer et al. They also include vertical semiconductor device geometries and vertical charge control. For example, U.S. Pat. No. 6,803,626 to Sap et al. discloses a MOSFET that includes at least two insulation-filled trench regions laterally spaced in a first semiconductor region to form a drift region there between, and at least one resistive element along the outer periphery. This arrangement minimizes the output capacitance of the MOSFET. U.S. Pat. Nos. 6,388,286, 6,764,889 and U.S. Patent Application 2002/0056884 all to Baliga also teach vertical MOSFETS with trenches containing gate electrodes and methods of making them. The reader will find still other modifications to vertically configured super-junction devices with epi layers taught by Boden, Jr. in U.S. Pat. No. 6,452,230. Also, a host of other semiconductor devices with vertical geometries and equipped with field shaping arrangements can be found in U.S. Pat. Nos. 6,184,555, 6,207,994, 6,462,377, 6,468,847, 6,541,817, 6,555,873, 6,639,272, 6,653,691, 6,706,615, 6,838,346 and U.S. Patent Application No. 2002/0195659.

It should be remarked that one major problem with super-junction transistors is their complicated device fabrication sequence. Precise charge balance is required for their operation, and that can only be achieved through an expensive multi-epitaxy process and the formation of multiple buried layers.

In an attempt to go beyond the super-junction limit an oxide-bypassed VDMOS structure is taught by Yung G. Liang et al. in “Oxide-Bypassed VDMOS (OBVDMOS): An Alternative to Superjunction High Voltage MOS Power Devices”, IEEE Electronic Devices Letters, Vol. 22, No. 8, August 2001, pp. 407-9. However, this technique relies on a metal-thick-oxide (MTO) structure to sustain the high electric field across the oxide (about 3 times higher than in Si) to achieve high drain-to-source breakdown voltage. This results in a number of manufacturing difficulties.

In U.S. Pat. Nos. 6,465,304, and 6,624,494 to Blanchard, the inventor teaches high power MOSFETs with voltage sustaining regions that include doped columns formed by trench etching and ion implantation. A number of technologies to be implemented in such MOSFET geometries as well as doping methods and fabrication techniques including terraced trenches are further discussed by the same inventor in U.S. Pat. No. 6,750,104 and U.S. Patent Applications 2003/0122188; 2003/.0181010; 2003/0203552; 2004/0097028; 2004/0009643; 2004/0110333; 2004/0157384; 2004/0164348; 2005/0042830. Furthermore, Blanchard also teaches including a floating island voltage sustaining members/layer in U.S. Patent Applications 2003/0068854 and 2003/0068863. Still further disclosure of semiconductor high-voltage devices with voltage sustaining layers or elements is provided by Chen in U.S. Pat. No. 5,726,469; 6,310,365 and U.S. Patent Applications 2003/0160281; 2005/0035406. In this group of prior art references the techniques and concepts are used to achieve breakdown voltages or junctions higher than the 1D theoretical limit with the aid of charge balance. This is equivalent to pinching off the high voltage terminal from the remainder of the device.

Despite the voluminous teachings in the art, achieving high breakdown voltages and low on-resistance in vertical semiconductor devices in a simple and low cost manner remains a challenge. This need is present in part, because of the many constraints that have to be satisfied at the same time, not the least of which is the ease of manufacture and robustness.

Objects and Advantages

In view of the above, it is an object of the present invention to provide a structure and method for obtaining high breakdown voltage V_{BD} in semiconductor devices, and in particular in vertical structure semiconductor devices, and more in particular still, in vertical structure high power semiconductor devices. The objective is to sustain high reverse voltages while simultaneously minimizing the on-resistance, Rₒₙ, or on-voltage Vₒₙ.

It is another object of the invention to provide a device structure that is easy to manufacture by ensuring that the device performance has suitable sensitivities to allow for acceptable manufacturing tolerances.

A further object of the invention is to provide a structure that achieves higher breakdown voltage than the theoretical 1D limit when operated in a reverse bias or reverse blocking state, while minimizing its “on” resistance when operated in its forward biased or forward conducting state.

These and other advantages and objects of the invention will become apparent from the ensuing description.

### SUMMARY

The objects and advantages of the invention are secured by a semiconductor device that has a top region, an intermediate region and a bottom region. The device has a controllable current path traversing any of these regions. The device has an insulating trench that is coextensive with the top and intermediate regions and girds the top and intermediate regions from at least one side and preferably from both or all sides. A series capacitive structure with a biased top element is disposed in the insulating trench. To maximize the breakdown voltage V_{BD}, which is typically needed when the device is reversed biased, the intermediate region is endowed with a capacitive property that is chosen to establish a capacitive interaction or coupling between the series capacitive structure and the intermediate region. The capacitive property of the intermediate region is established by an appropriately chosen material constitution, which may include adjusting the doping level or the dielectric constant of the intermediate region. Furthermore, the capacitive interaction can be controlled by a predetermined constitution of the insulating trench. For example, the predetermined constitution can be can be achieved by adjusting the thickness of the dielectric or the dielectric constant of the insulating trench.

In some embodiments, the semiconductor device of invention is constructed such that the top region is an anode of a first conductivity type, and the intermediate region and bottom regions are of a second conductivity type. In such embodiments it may further be desirable that the bottom region have a higher doping level than the intermediate region. When the semiconductor device is thus constructed, the bottom region can serve as a cathode and the device structure can be used to construct a diode. In other embodiments additional regions can be added, e.g., a source region in the anode region to serve as a source of conducting carriers and the device structure can be employed to construct a transistor.

The series capacitive structure has a top element that is appropriately biased, e.g., grounded, and a number of floating elements. The elements of the capacitive structure can be made of many different materials including conductors as well as semiconductors. In a preferred embodiment the floating elements are shaped as plates that are mutually parallel and spaced apart by certain spacings. The spacings can be equal or not, depending on the desired capacitive interaction.

The insulating trench within which the series capacitive structure resides, preferably has an oxide, e.g., silicon dioxide as the dielectric. In one particular embodiment the structure includes polysilicon plates surrounded by silicon dioxide. Furthermore, it is advantageous to adjust the geometry of the biased top element of the capacitive structure to further maximize the breakdown voltage V_{BD}. The variations may include the general shape as well as thickness of the top element.

The device of invention requires an appropriate terminating structure. Suitable structures include field plates as well as self-terminating structures. In some embodiments the top element of the capacitive structure can itself be a field plate.

The device of invention can be used as the basic structure for constructing various electronic as well as photo-electronic components or portions thereof. For example, in some embodiments the intermediate and bottom regions are suitably doped and configured to serve as a drain region of a transistor. In fact, the final component employing the device of invention can be, among other, a transistor, bipolar transistor, MOSFET, JFET, thyristor or diode.

The breakdown voltage V_{BD} in the controllable current path traversing any or all of the top, intermediate and bottom regions of a semiconductor device is maximized by providing an insulating trench that is coextensive with and girds the top and intermediate regions. The series capacitive structure is disposed in the insulating trench and its top element is biased. A capacitive property of the intermediate region is adjusted to establish capacitive coupling between the series capacitive structure and the intermediate region so as to maximize the breakdown voltage V_{BD}. In some embodiments, the capacitive coupling is adjusted through altering a material constitution of the intermediate layer, e.g., its doping level or dielectric constant. In other embodiments, the capacitive coupling is adjusted through selecting a certain constitution of the insulating trench, e.g., thickness or dielectric constant of the insulating material making up the trench.

The invention further extends to semiconductor devices that employ cells that have controllable current paths with insulating trenches and series capacitive structures that obtain high breakdown voltages by establishing a capacitive coupling between the capacitive structures and the intermediate regions. For example, some electric or photoelectric components can use a number of such cells. These cells can be adjacent and even share some of the series capacitive structures.

Although conventional device termination techniques (e.g., floating rings, reduced surface field termination, and junction termination) are applicable to FCC devices, a preferred FCC termination technique makes use of a second FCC structure to terminate an active device including a first FCC structure. Such FCC self-termination provides a low area device termination having a fast response time.

A detailed description of the preferred embodiments of the invention is presented below in reference to the appended drawing figures.

### BRIEF DESCRIPTION OF THE DRAWINGS

FIG. 1 is a simplified three-dimensional partial schematic diagram (half-cell) illustrating the basic components and principles of operation of a semiconductor device according to the invention.

FIG. 2 is a complete front schematic view of the simplified diagram of FIG. 1 illustrating the principles of maximizing the breakdown voltage V_{BD} according to the invention.

FIG. 3 is a diagram illustrating the voltage division effect produced by the elements of the capacitive structure of the device of FIG. 1.

FIG. 4 is a graph illustrating the voltage drop across the capacitive structure of the device of FIG. 1.

FIG. 5 is a partial schematic diagram (half-cell) of a prior art VDMOS transistor.

FIG. 6 is a partial schematic diagram (half-cell) of a FCCFET according to the invention.

FIG. 7 is a schematic diagram of a surface portion of the FCCFET of FIG. 6.

FIG. 8 is a graph of the voltage drop in the capacitive structure of the Floating Capacitor Coupled Field-Effect-Transistor (FCCFET) of FIG. 6.

FIG. 9 is a plot of equipotential or field lines for a FCCVDMOS device based on the structure of FCCFET of FIG. 6.

FIGS. 10A-C illustrate the behavior of a perfectly manufactured FCCFET in accordance with the invention.

FIGS. 11A-C illustrate the behavior of an FCCFET manufactured with an imperfection in the capacitive structure.

FIGS. 12A-B are graphs of the breakdown performance and coupling ratio of a particular FCCFET rated at V_{BD}=680 V according to the invention under application of a dc voltage.

FIGS. 13A-B are graphs of the breakdown performance and coupling ratio for the 680 V FCCFET under application of a 1 ns 680 V pulse.

FIGS. 14A-B are graphs of the breakdown performance and coupling ratio for the 680 V FCCFET under application of a 0.1 ns 680 V pulse.

FIG. 15A illustrates an FCC VDMOS in accordance to the invention.

FIG. 15B illustrates an Oxide-bypassed VDMOS (OBVDMOS) having an identical device structure as the FCC VDMOS of FIG. 15A.

FIG. 16 is a plot illustrating the specific on-resistance Rₒₙ versus breakdown voltage V_{BD} for a power semiconductor in accordance with the invention.

FIG. 17 is a full-cell view of another embodiment of an FCCFET device according to the invention.

FIGS. 18A-B illustrate two different terminating structures compatible with a semiconductor device in accordance with the invention.

FIGS. 19A-D illustrate several alternative geometries for series capacitive structures in accordance with the invention.

FIG. 20 shows an example of capacitive field plate termination in accordance with an embodiment of the invention.

FIG. 21 shows a top partial view of the capacitive field plate termination of FIG. 20.

FIG. 22 shows an example of resistive field plate termination in accordance with an embodiment of the invention.

FIG. 23 is a plot of breakdown voltage vs. termination region width for an example according to FIG. 22.

FIG. 24 shows an example of FCC-termination according to an embodiment of the invention.

FIG. 25 is a plot of breakdown voltage vs. termination region width for an example according to FIG. 24.

### DETAILED DESCRIPTION

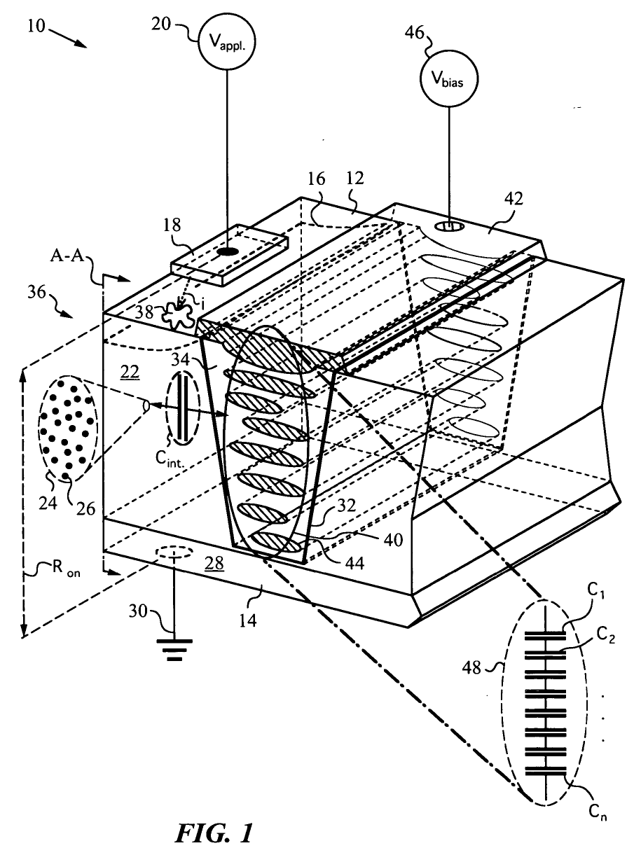

The present invention will be best understood by first reviewing the basic principles based on the partial (half-cell) and simplified three-dimensional schematic diagram of a semiconductor device 10 according to the invention as shown in FIG. 1. Device 10 has a top surface 12 and a bottom surface 14 parallel to surface 12. A top region 16 has a first conductivity type established by p-type doping and it extends directly below top surface 12. An electrical contact 18 to top region 16 is established by a metallization or any other suitable contacting method. Contact 18 is in electrical communication with a voltage source 20 for applying an applied voltage Vₐₚₚ₁ to top region 16.

An intermediate region 22 of a second conductivity type, in the present case provided by an n-type doping extends below top region 16. Intermediate region 22 is made up of a material 24 that has a certain material composition or constitution 26, as illustrated in the magnified view in dashed lines. A bottom region 28 of the same conductivity type as intermediate region 22, i.e., n-type and it lies underneath region 22.

Device 10 has an insulating trench 32 that has a certain material composition or constitution. In the present embodiment, trench 32 is coated with an insulating material 34 such as oxide. Trench 32 is coextensive with top and intermediate regions 16, 22 and braces or girds those regions from one side, more specifically from the right side.

Device 10 can be, e.g., a diode or a transistor. In the first case a controllable current path 36 traverses top region 16, intermediate region 22 and bottom region 28. In such case, top and bottom regions 16, 28 are forward biased. When forward biased as shown, path 36 is in a conducting state in which a current i can flow from top region 16 via any suitable geometrical path 38, e.g., straight or folded through the bulk of device 10 to bottom region 28. In the present embodiment bottom region 28 also serves as a cathode of device 10 and is connected to a common or ground voltage 30, V_{gnd}.

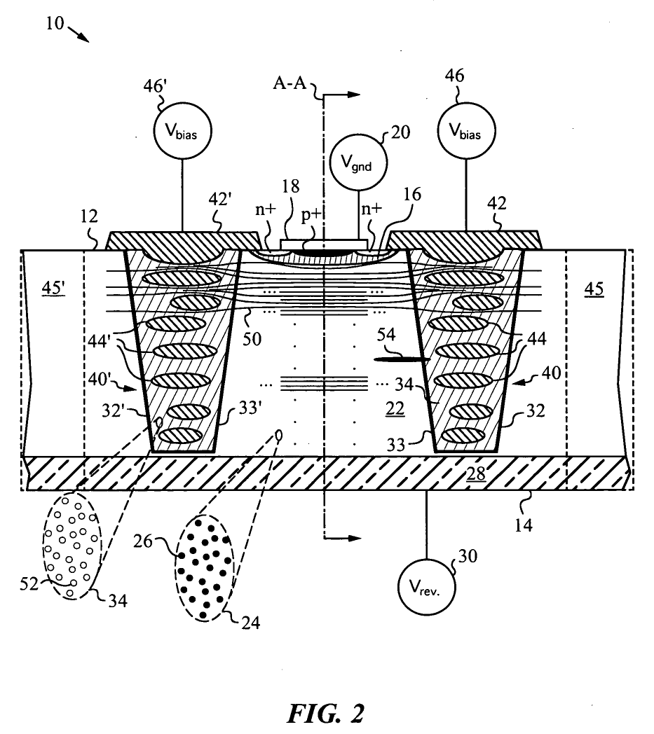

When device 10 is configured to operate as a transistor current path 36 traverses top region 16 to a biased top element 42 of a series capacitive structure 40. In this case top region 16 can have an n+diffused region for a source and p+ diffused region for a p-type pickup (see FIG. 2). Top element 42 serves as a gate in this embodiment and hence a bias voltage V_{bias} applied to top element 42 is a gate bias or V_{gate}. Contemporaneously, applied voltage Vₐₚₚ₁. or V_{source} is at a potential that is lower than V_{gate}, or usually at ground potential. In other words, p-type region 16 is always reverse biased, and conduction is achieved by modulating the resistance under gate 42 through V_{bias} 46. At the same time, voltage 30 is at a positive bias. Under this condition device 10 operates as an enhancement-mode n-channel transistor. In a blocking mode, V_{gate} and V_{source} are at the same potential, usually ground, and a high “+” potential V_{rev.} is applied to region 28. A person skilled in the art will recognize that other configurations are possible, e.g., if one desired to configure device 10 as a p-channel transistor.

In any specific configuration of device 10 desired, it is important that series capacitive structure 40 with biased top element 42 be disposed in insulating trench 32. Structure 40 extends along the vertical direction and has a number of floating elements 44 located under biased top element 42. Top element 42 and floating elements 44 can be made of any suitable material including conductors and semiconductors. In the present embodiment all elements 42, 44 are made of polysilicon.

An equivalent circuit 48 illustrating the series capacitances C₁, C₂, . . . , Cₙ between neighboring elements 42, 44 is shown in the magnified view drawn in dashed lines. Capacitive structure 40 also experiences a certain capacitive interaction or coupling with intermediate region 22 as generally indicated by C_{int.}. In fact, intermediate region 22 has a chosen capacitive property for establishing capacitive coupling C_{int.} between capacitive structure 40 and intermediate region 22 so as to maximize breakdown voltage V_{BD} in current path 36 when device 10 is in a reverse biased or blocked state and preserving low on-resistance Rₒₙ when device 10 is in a forward biased or conducting state.

The mechanism by which breakdown voltage V_{BD} in current path 36 is maximized will be better understood by referring to the complete or full-cell front schematic view of FIG. 2, which illustrates a section along line A-A of FIG. 1. In FIG. 2 device 10 is completed by a second insulating trench 32′ that is coextensive with and girds regions 16, 22 from the left side. Because the parts on the left side correspond to those of trench 32 girding current path 36 from the right side corresponding elements are called out with corresponding primed references. These include, among others, a capacitive structure 40′ composed of elements 42′, 44′. In addition, terminations 45, 45′ are provided on both sides of device 10. Although most well-known terminations 45, 45′ can be used in device 10, ones that are particularly well-suited will be discussed in conjunction with specific embodiments discussed below.

Breakdown voltage V_{BD} in controllable current path 36 typically requires maximization when path 36 is in the reverse biased or blocked state (i.e., non-conducting state). When device 10 is an n-channel transistor this state occurs when a blocking voltage or reverse bias _{Vrev.} that is positive is applied across device 10 and hence no current i flows. In the present embodiment contact 18 is contemporaneously grounded at a common or ground potential V_{gnd.} along with gate voltage V_{gate} rather than being allowed to float while reverse voltage V_{rev.} is applied.

As reverse voltage V_{rev.} increases, equipotential lines 50 become more and more bunched together in areas where the electric field E is maximum. Based on well-known principles of electricity and magnetism, bunching of lines 50 first occurs at junctions (i.e., interface corners and edges) between different regions of device 10. Note that bunching of lines 50 is most acute at junctions that have high curvatures. Electric breakdown due to impact ionization will take place at those junctions when reverse voltage V_{rev.} exceeds a breakdown voltage V_{BD} at which the materials in those junctions are no longer able to support the local electric field E.

In accordance with the invention, the distribution of equipotential lines 50 is homogenized or shaped with the aid of capacitive structures 40, 40′ that are coextensive with and gird top and intermediate regions 16, 22. The shaping, or homogenization of the distribution of equipotential lines 50 is adjusted by capacitive coupling C_{int.} between capacitive structures 40, 40′ and intermediate region 22. This is accomplished by endowing intermediate region 22 with an appropriately chosen capacitive property.

In a preferred embodiment, the capacitive property of intermediate region 22 is established by a material composition or constitution 26 of material 24, and more specifically by adjusting a level of a dopant 26 within material 24. That is because adjusting the level of dopant 26 is an effective mechanism for adjusting volumetric or bulk capacitance of intermediate region 22. It will be appreciated by one skilled in the art that bulk capacitance can be adjusted in many ways including changing the dielectric constant of material 24. Thus, the meaning of material constitution 26 extends beyond dopants to various material additives, admixtures as well as changes to structural aspects of material 24 and any other material alterations to the extent that these adjust bulk capacitance of intermediate region 22.

In most applications, region 22 is made of semiconducting material 24 such as Si, SiC, GaN, GaAlN, GaAs, SiGe, Ge. The selection of dopant 26 depends on material 24. For example, when n-type doping is used and material 24 is Si or SiGe then dopant 26 is preferably phosphorus or arsenic. When n-type doping is used and material 24 is SiC then dopant 26 is nitrogen or phosphorus, and when material 24 is GaN then dopant 26 is silicon.

The concentrations of dopant 26 depend on the specifications of device 10 and material 24. For example, when using silicon as material 24 the concentration of dopant 26 can range between 1×10¹⁵-5×10¹⁵/cm³ when one desires a breakdown voltage V_{BD} of 500 V or higher. Concentration of dopant 26 should be reduced for higher breakdown voltages and increased for lower breakdown voltages. When material 24 has a wider bandgap than Si, e.g., material 24 is SiC and GaN, then the concentrations of dopant 26 to achieve the same-breakdown voltages as in the case of Si can be 5 to 15 times higher.

In the preferred embodiment capacitive coupling C_{int.} between intermediate region 22 and capacitive structure 40 is further adjusted by controlling a constitution 52 of insulating trenches 32, 32′ that are filled with insulating material 34. Constitution 52 is preferably a material composition or other material property that affects the dielectric constant k as shown in the magnified view of material 34. Alternatively, constitution 52 can be any material additive, admixture, structural change to material 34 or any other material alteration affecting the volumetric capacitance of trench 34 or its dielectric constant k.

Still further adjustment of capacitive coupling C_{int.} between intermediate region 22 and capacitive structure 40 is achieved by adjusting the thickness of dielectric material 34. The effect of varying thickness is inversely proportional to capacitive coupling C_{int.}.

Among the various available insulators the preferred insulating material 34 is SiO₂ or Si₃N₄ with dielectric constants k of 3.9 and 7.5 respectively. Material 34 can also be SiₓO_{y}N_{z} with dielectric constant k between that of oxide and nitride depending on composition 52 and adjustments during the deposition (e.g., by varying the gas concentrations). In a particular embodiment, a 55 μm “single-layer” Si n-epi with doping on the order of 1-2×10¹⁵ /cm³, SiO₂ dielectric in the insulating trench with sidewall oxide thickness in the range of 0.7-2.9 μm, bottom thickness 1-10 μm, interlayer oxide 0.15-0.35 μm yields a breakdown voltage V_{BD} in excess of 600 V.

During operation, biased element 42 and floating elements 44 have a homogenizing or field shaping effect on the electric field E. The field shaping effect is three-dimensional and it takes place throughout intermediate region 22. As a result, the distribution of equipotential lines 50 along the vertical direction within intermediate region 22 where breakdown is likely to occur and is to be avoided becomes homogenous. More precisely, equipotential lines 50 in intermediate region 22 are forced to be “concave” due to the lower potential voltages on elements 44 relative to voltages in adjacent drift or intermediate region 22.

The mechanism responsible for the three-dimensional field shaping that produces concave equipotential lines 50 is a dynamic potential or voltage division effect between successive elements 42, 44. This capacitive voltage divider effect is rapid and efficient because it is aided by the controlled capacitive coupling C_{int.} between intermediate region 22 and capacitive structure 40. More precisely, field shaping can occur within response times on the order of 1 ns. Such response time is sufficient for most applications of power devices. On time scales shorter than 1 ns, a time delay starts to develop on elements 44 and early breakdown occurs at a trench sidewall 33, as discussed below.

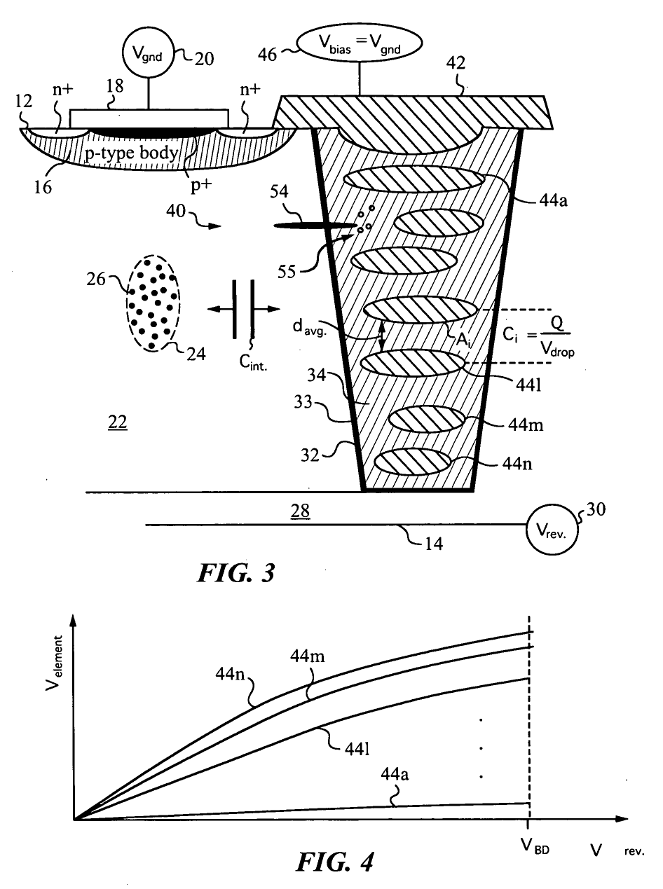

The mechanics of the three-dimensional field shaping effect will be better understood by first examining the voltage drops between successive pairs of elements 42, 44. These voltage drops depend on many factors, including element geometries and spacings as better illustrated in FIG. 3. Thus, for any pair of elements 42, 44 the capacitance between them Cᵢ is defined by:

$${C}_{i} = \frac{Q}{{V}_{i}} ,$$

where Vᵢ is the voltage drop between the elements and Q is the accumulated charge. For the particular elements 44 making up capacitor Cᵢ the capacitance can be further defined by noting that elements 44 resemble facing parallel plates of area Aᵢ and material 34 has dielectric constant k. Thus, one can define:

$${C}_{i} ≅ \frac{k {ɛ}_{o} {A}_{i}}{{d}_{avg}} ,$$

where εₒ is the permeability of free space and d_{avg.} is the average spacing between elements 44. Of course, in embodiments where elements 44 deviate from that model an exact derivation from Gauss Law is necessary. In general, however, when elements 42, 44 of structure 40 are essentially aligned, of the same size and their average spacings d_{avg.} are substantially equal, then Vᵢ can be approximated as:

$${V}_{i} ≅ \frac{{Qd}_{avg}}{k {ɛ}_{o} {A}_{i}} ≅ \frac{{V}_{rev .}}{n} ,$$

where n is the number of capacitors in structure 40, excluding element 42.

Lateral capacitive coupling C_{int.} between structure 40 and intermediate region 22 plays an important effect on the response time and efficiency of field shaping. Namely, when voltage V_{rev.} is a pulse that is longer than 1 ns then capacitive coupling C_{int.} ensures that floating elements 44 respond to the applied pulse with a coupling ratio that is essentially equivalent to the situation where voltage V_{rev.} is constant (dc). In other words, voltage V_{rev.} is divided or dropped in incremental steps Vᵢ between each successive pair of elements 42, 44 from V_{rev.} down to V_{gnd}. It should be noted, that some of voltage V_{rev.} is also dropped between bottom most element 44n and bottom surface 14, which is actually maintained at voltage V_{rev.}.

Since the electric field distribution over structure 40 is monotonic over floating plates it guarantees that the overall voltage drop is well-behaved or essentially linear. Capacitive coupling C_{int.} with intermediate region 22 ensures that this condition holds for pulses V_{rev.} that are longer than 1 ns. The same therefore extends to equipotential lines 50. The graph in FIG. 4 illustrates an exemplary distribution of voltages on successive elements 44 under such conditions.

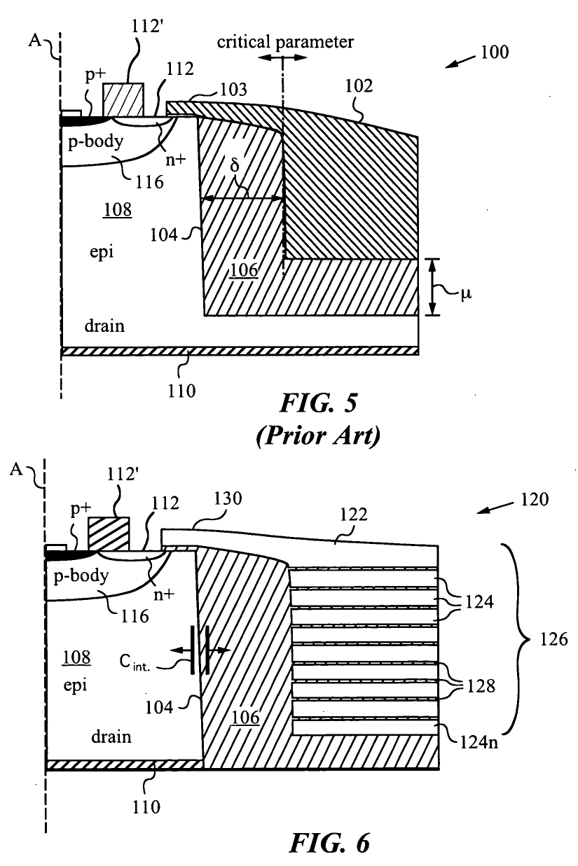

For V_{rev.} pulses shorter than 1 ns capacitive coupling C_{int.} is no longer able to enforce a linear voltage drop over structure 40. This is due to the Miller effect or Miller capacitance that affects the frequency response of device 10. As a result, breakdown occurs in breakdown regions 54 typically along sidewall 33 of insulating trench 32. The breakdown causes hot carriers 55 to be injected into material 34 and structure 40 and thus perturbs the capacitive coupling ratios between the successive elements 44. It should be noted, however, that device 10 of the invention exhibits good switching characteristics when compared to other vertical or trench devices (e.g., MOSFETs) since the “active” gate/drift overlapping area is only at the top biased element 42 that has a depth comparable to a p-body junction (see embodiment in which the device of invention is adapted for use as a transistor as described below, e.g., device 120 in FIG. 6).

When device 10 is operated in the forward biased or conducting mode, the on-resistance Rₒₙ of device 10 is minimized since there is no depletion layer formed along sidewalls 33, 33′ of insulating trenches 32, 32′. This results in a lower resistance per unit area compared to prior art structures that use p-n junctions to achieve charge balance. In particular, in prior art structure, e.g., super-junction structures the p-n junctions have depletion layers that reduce the available “volume” of n-type drift region for conduction. In contrast, device 10 does not suffer from reduction of the available “volume” for carrying current i.

Based on the above-described principles a variety of specific semiconductor devices can be built. Their particular construction is dictated by application-specific parameters. The below embodiments describe a select number of such semiconductor devices to show a person skilled in the art how to apply the present teachings under particular circumstances. Clearly, these specific embodiments are provided for illustrative purposes only and are non-limiting to the scope of the invention.

A first specific embodiment of the invention is a field effect transistor (FET) that will be referred to as a floating capacitor coupled FET or FCCFET. A half-cell of a prior art FET in conventional Oxide-Bypassed VDMOS is shown in FIG. 5 for comparison. The right half-cell delimited by line A illustrates a conventional FET 100 with a vertical double-diffusion metal oxide semiconductor (VDMOS) structure 102 composed of a surface poly gate 103 as the active device for carrier supply. Structure 102 extends into an insulating trench 104 filled with an insulating material 106, typically an oxide. A drift region 108 is made of epitaxial (epi) layers and a bottom or drain region 110 corresponds to the metallization. Transistor 100 has a source 112 (with source contact 112′) and a p-body 116 separating it from gate 103. The operation of transistor 100 and similar devices is well known to those skilled in the art.

Unfortunately, the exact thickness and resistivity of oxide 106 have to be rigorously monitored to control breakdown. Specifically, sidewall thickness δ of oxide 106, and bottom thickness μ of oxide 106 or the metal-thick-oxide (MTO) 108 need to be precisely controlled. The most critical parameter is indicated in the dashed and dotted line. Because of these stringent requirements Oxide-Bypassed VDMOS FET 100 is difficult and expensive to manufacture.

FIG. 6 illustrates a half-cell of a floating-capacitor-coupled FET 120 or FCCFET that overcomes the prior art limitations. For easier comparison corresponding parts of FCCFET 120 use the same reference numerals as in FIG. 5. Instead of structure 102, FCCFET 120 has a top element 122 (including a gate 130) and a number of floating elements 124 buried in trench 104 filled with insulating material or dielectric 106. In accordance with the invention, trench 104 is coextensive with and girds from the right side top region, here p-body 116, and intermediate region, here epi drift region 108. Elements 124 are floating because each is insulated from the other as well as the remainder of FCCFET 120 by insulating material or oxide 106. In the present case oxide 106 is SiO₂, though a person skilled in the art will recognize that other types of insulating materials such as nitrides, oxynitrides, silicon rich oxides, silicon nitride and other well-known insulating materials can be used as well. Together, top element 122 and elements 124 form a series capacitive structure 126. It is the presence of structure 126 that renders FET 120 a floating-capacitor-coupled FET according to the invention.

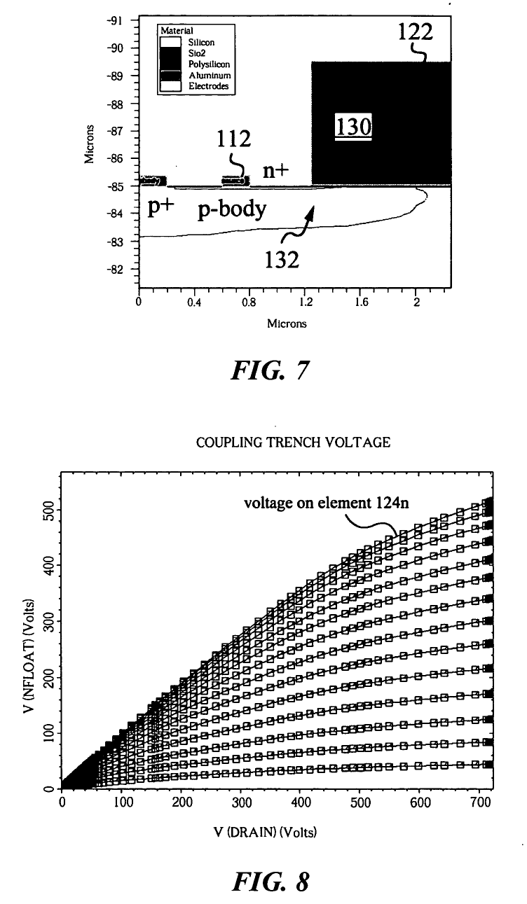

The enlarged view of a surface portion of device 120 in FIG. 7 illustrates how a standard VDMOS serves as the carrier source at the surface of device 120 while trench 104 is etched down all the way to the more heavily doped substrate. In this case top element 122 has a portion 130 that serves as the transistor gate and a transistor channel 132 extends along the surface as indicated. Top element 122 is heavily doped and electrically contacted to control the on/off state of the transistor.

The lateral thickness of dielectric 106, especially near the top of FCCFET 120 can vary by a large amount. Note however, that the thickness of dielectric only has to be thick enough to sustain the electric field before it leaks (e.g. 6 MV/cm for thermal oxide to leak), and with the descending characteristic of potential lines towards the top, dielectric thickness can vary quite substantially on the top of structure 126. In other words, thickness of dielectric 106, or δ (see FIG. 5) is not a critical parameter as it was in the prior art device 100 show. This renders FCCFET 120 easier to manufacture because of relaxed tolerances.

In the present embodiment top element 122 is a plate and floating elements 124 are also plates. All plates 122, 124 are made of polysilicon. Plates 122 and 124 are mutually parallel and separated by certain spacings 128. Unlike device 10 in which the spacings were unequal, FCCFET 120 preserves equal spacings 128 between plates 122, 124 in order to linearize the voltage drop Vᵢ from plate to plate as much as possible. Meanwhile, the surface areas Aᵢ of plates 122, 124 decrease from top plate 122 to bottom plate 124. As a practical matter, it is noted that in some cases plates 122, 124 may not be completely separated, and that shorts may exist due to variations in design or fabrication issues, such as defects in oxide 106 or processing errors. These shorts may render some subsets of plates 122, 124 equipotential, but should be avoided if at all possible, since shorting acts to lower the voltage dividing and field shaping capability of structure 126.

Epi drift region 108 has a certain property for establishing a capacitive coupling Cᵢₙₜ. between series capacitive structure 126 and epi 108. The property in the present case is the doping level of epi 108. In particular, drift region epi 108 is made of Si and can have either uniform, stepped, or graded doping profile. Si epi 108 has a doping in the range of 1×10¹⁵-5×101¹⁵/cm³ with thickness of 50-60 μm.

With these parameters epi 108 is capable of achieving breakdown voltage >650 V, thereby maximizing the breakdown voltage in the current path between regions 116, 108, 110. In addition, oxide 106 has a predetermined constitution for participating in establishing capacitive coupling C_{int.}. Note that no metal-thick-oxide (MTO) is required in trench 104, neither at the sidewall or bottom. Thickness of dielectric 106 depends on dielectric constant k, number of floating plates 124, and doping level of the drift region 108. 1-2.5 μm thickness of SiO₂ at sidewall and bottom of trench 104 is sufficient for a 650 V Si device 120 with 7 floating electrode plates 128 in trench 104.

During operation plates 122, 124 act as a vertical capacitive voltage divider between the drain voltage applied on the bottom region 110 and biased top plate 122. The offset voltage between floating polysilicon plates 124 and adjacent epi drift region 108 provides field bypass/shaping effects in drift region 108. The highest breakdown occurs when drift region 108 between trenches (only trench 104 shown in the half-cell view of FIG. 6) is completely depleted by this lateral electric field, or when minimum spacing is achieved between all the equipotential lines (see FIG. 2). In FCCFET 120 the electric field distribution or shape would be “convex” in the absence of structure 126 and its coupling C_{int.} with drift region 108. This is typically the case for a plane p-n junction. However, with the aid of structure 126 the equipotential lines are redistributed or shaped such that the electric field distribution is “concave”. The “concave” distribution results in a higher breakdown voltage V_{BD}. In this embodiment it is also advantageous to field plate the p-n junction laterally.

The “concave” field lines in intermediate region 108 are caused by the lower potential on floating plates 124 in relative to immediate adjacent drift region 108. The magnitude of voltage offset is determined by the coupling ratio. However, this is not made possible if the surface p-n junction still has convex field. The biased poly gate 130 acts as a top field plate to shape the field lines around surface p-n junction concave, and hence enables the underneath floating electrodes 124 to follow in the same fashion for breakdown enhancement.

In fact, FCCFET 120 is capable of achieving a breakdown voltage V_{BD}=720 V and an on-resistance Rₒₙ=7 mΩ-cm², with 55 μm thick Si epi 108 made of 3 layers with doping levels of 2×10¹⁵, 3×10¹⁵, and 4×10¹⁵/cm³ for top, middle, and bottom respectively. It should be noted that overall epi 108 should have a well-controlled resistivity and thickness in order to avoid oxide surface breakdown leading to breakdown walking and/or injection of carriers into floating elements 124.

One of the key features of FCCFET 120 is that a voltage applied to drain 110 decreases linearly along the floating capacitor plates, as shown in the graph of FIG. 8. The linear decrease occurs because of the voltage division effect achieved in accordance with the invention by the coupling ratio over floating elements 124 and top element 122 of series capacitive structure 126. This linear decrease allows one to use a much thinner bottom trench oxide 106 with no stringent thickness control, unlike bottom thickness μ that has to be very well controlled in the prior art device shown in FIG. 5. In fact, the thickness of bottom oxide 106 only has to be sufficient to sustain the voltage difference between drain 110 and the bottom-most element 124n. This thickness can be as little as 4 μm for a 200 V difference when V_{BD}=720 V, given 6 MV/cm electric field for thermally grown SiO₂ to leak.

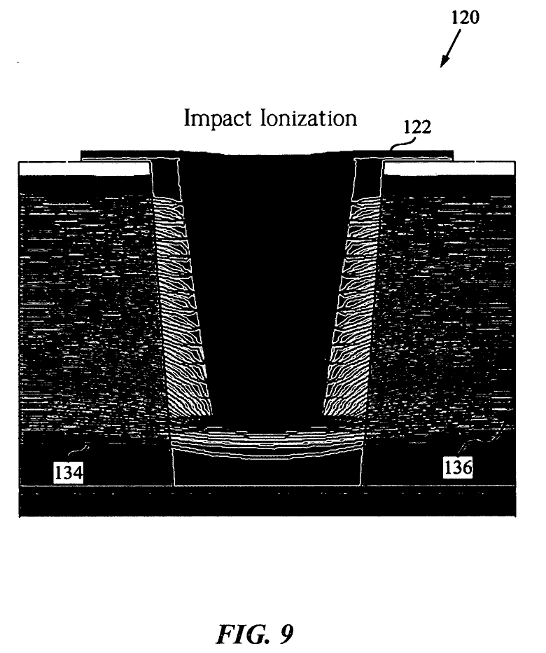

FIG. 9 illustrates the relatively uniform distribution of equipotential or field lines 134 obtained in device 120. In this case device 120 is an FCCVDMOS. The initial plotted potential is 100 V and each field line represents a 10 V incremental difference. Note the location of a highest impact ionization region or breakdown region 136 where lines 134 exhibit the closest spacing.

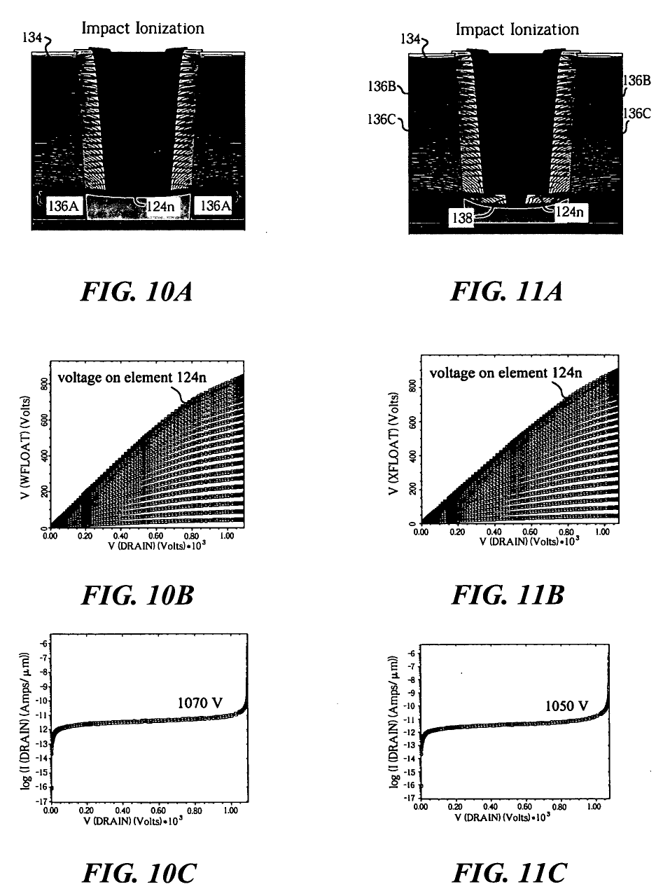

In practice, the processing of a FCCFET may not necessarily result in perfectly flat bottom oxide 106, especially if a nitride spacer at sidewall of trench 104 is used to thermally grow thicker bottom oxide 106 after the second trench etch. FIGS. 10A-C and 11A-C illustrate the effect of an imperfection, specifically a protruding tip 138 in bottom-most floating plate 124n at the bottom of trench 104. FIG. 10A shows a perfect structure with field lines 134 and breakdown region 136A. FIG. 10B illustrates the voltages on the 23 floating plates 124 in perfect device 120, and FIG. 10C illustrates its breakdown behavior. A corresponding imperfect structure of device 120 is shown in FIG. 11A. The imperfect structure has two breakdown regions 136B, 136C. Note, however that the voltages on its 23 floating plates 124 and its breakdown behavior are only slightly affected. In fact, the breakdown voltage V_{BD} decreases only by 20 V, specifically from 1070 V for the perfect device to 1050 V for the imperfect device with tip 138.

The reason for the relatively constant breakdown voltage and change in breakdown location is the presence of protruding tip 138, which provides for extra field shaping at the bottom of trench 104. The effect of that shaping is to move the highest concentration of field lines 134 toward the middle layers of epi 108. However, since device 120 does not require metal-thick-oxide (MTO) at bottom of trench 104, 0° fluorine implant into the silicon substrate after trench etch prior to oxidation is typically sufficient to grow thicker trench bottom oxide 106 at an accelerated rate while simultaneously growing conventional oxide at sidewalls of trench 104. The results indicate a 2-3 fold increase in thickness of oxide 106 with a 0° fluorine implantation under optimal conditions, which are described, e.g., by D. S. Woolsey in “Enhanced Discrete DMOS Power Trench Gate Oxide Growth”, Solid State Technology, 2002. Clearly, this level of insensitivity to defects and ability to speed up the manufacturing process is very advantageous for fabrication.

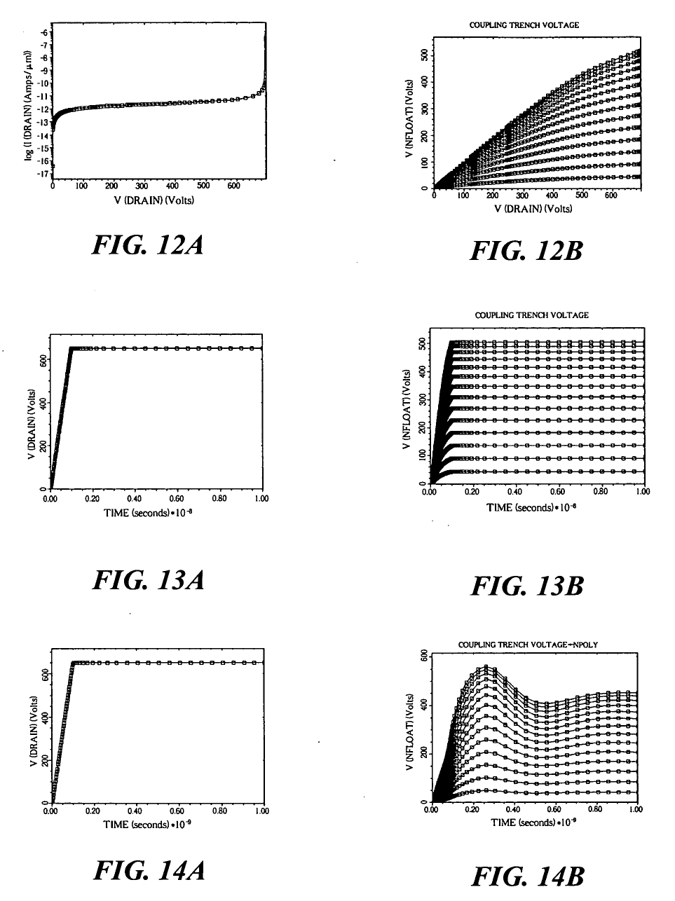

When an FCCFET is used in a power device as a switching element, its transient behavior becomes very important. The behavior of a specific FCCFET made in accordance with the method of invention and found to have a breakdown voltage V_{BD}=680 V in the dc mode is shown in Figs. 12A-B. Specifically, FIG. 12A is a graph illustrating the breakdown behavior and FIG. 12B is a plot showing the coupling ratio or voltages on the individual floating plates under the dc condition. For comparison, FIGS. 13A and 13B show the breakdown behavior and coupling ratio in response to a 1 ns 650 V pulse. No delay is observed and the coupling ratio remains the same as under the dc condition. FIGS. 14A and 14B show the breakdown behavior and coupling ratio in response to a 0.1 ns 650 V pulse. Note that floating plates no longer follow the high voltage applied on the bottom, leading to early breakdown along the trench sidewall and injection of hot carriers into the plates of the series capacitive structure and affecting the potentials of the floating plates.

Device parameters affecting transient behavior of the FCCFET include epi resistivity and oxide thickness (sidewall, bottom and inter-poly) that contribute to the RC time constant or delay time. Thus, the RC time constant should be optimized for both steady-state and dynamic breakdown. A person skilled in the art will appreciate that such optimization can be performed based on standard knowledge in the field of electricity and magnetism and will further improve the performance of the FCCFET.

A trench-gate DMOS has the lowest resistance in its class because it has the highest Z/A ratio, or total conducting channel per unit area. Turning a conventional Oxide-bypassed DMOS to a trench-gate DMOS is possible by more complicated processing steps. Meanwhile, with an FCCFET according to the invention the conversion is made simple. What is required is a thin sidewall oxide just thick enough to sustain the voltage difference generated by the descending coupling ratio towards the surface, but not the full-scale lateral voltage drop across unit-potential poly and drift epi as is the case for an Oxide-bypassed DMOS. This aspect of the invention enables side-wall oxide that is thin enough to transform a vertical DMOS to a trench-gate DMOS with a reasonable threshold voltage for further reduction in specific on-resistance, where the channel is now along a sidewall of trench 104. In fact, an FCC trench-gate DMOS has a higher breakdown voltage than an FCC VDMOS given identical device parameters (e.g., epi, number of floating elements, sidewall and bottom oxide thickness), that is at least partly due to the absence of curvature in the p-n junction.

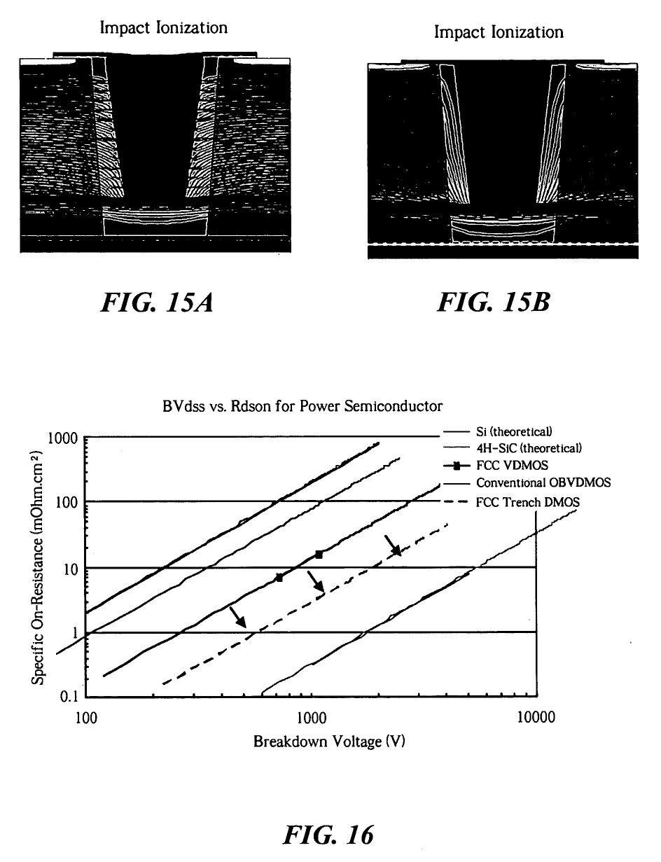

The break-through performance of an FCCFET is further illustrated by comparing it and an Oxide-bypassed FET, having identical device structure including the same epi thickness/resistivity, sidewall/bottom trench oxide, composite width, etc., as shown in FIGS. 15A and 15B. Note that the FCC technique embodied in the device of FIG. 15A improves a plane 140 V p-body/n-epi p-n junction breakdown more than five-fold or up to 720 V. In comparison, the Oxide-bypassed scheme shown in FIG. 15B is limited by dielectric breakdown at the thin sidewall oxide and thus only improves breakdown about 1.5 fold raising it to 220 V.

A person skilled in the art will recognize that devices according to the invention may exhibit all possible variations such as having stripe cells, cellular cells, integration of shallower trench-gate DMOS between floating trench field plates all aimed to increase the total channel periphery or Z/A ratio.

FIG. 16 is a plot illustrating the performance of an FCCFET according to the invention in decreasing the on-resistance while increasing breakdown voltage. This particular device uses VDMOS as the carrier source; i.e., it is a FCCVDMOS. As is clear from the graph, the performance of the FCCVDMOS is better than that of the conventional OBVDMOS by nearly one order of magnitude. Further improvement is possible by engagement of trench-gate DMOS with higher breakdown voltage and lower on-resistance, approaching the SiC limit.

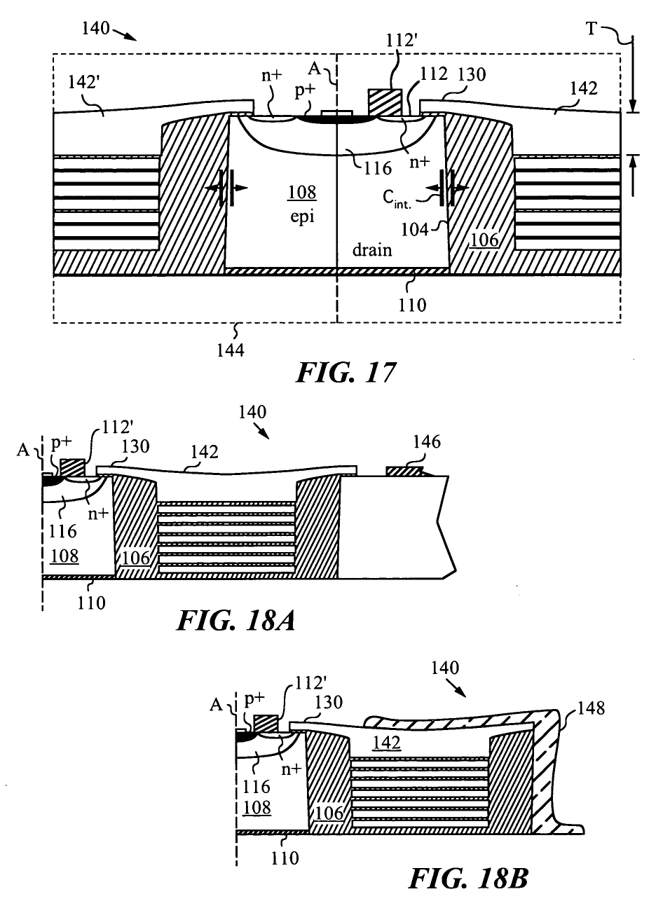

FIG. 17 illustrates a full-cell view of another embodiment of a device 140 similar to device 120 of FIG. 6. Device 140 is symmetric about cell center axis A and, for simplicity, the same reference numerals as used in FIG. 6 are used to designate corresponding parts. Device 140 has a top element 142 that serves as gate 130 but whose geometry is modified in comparison to top element 122. In particular, top element 142 has a certain thickness T to allow it to reach deeper into trench 104; it reaches deeper than the p-junction. By doing this, element 142 actually forms an integrated field plate that aids in further maximization of breakdown voltage V_{BD}. On the other side of cell 144 element 142′ mirrors element 142.

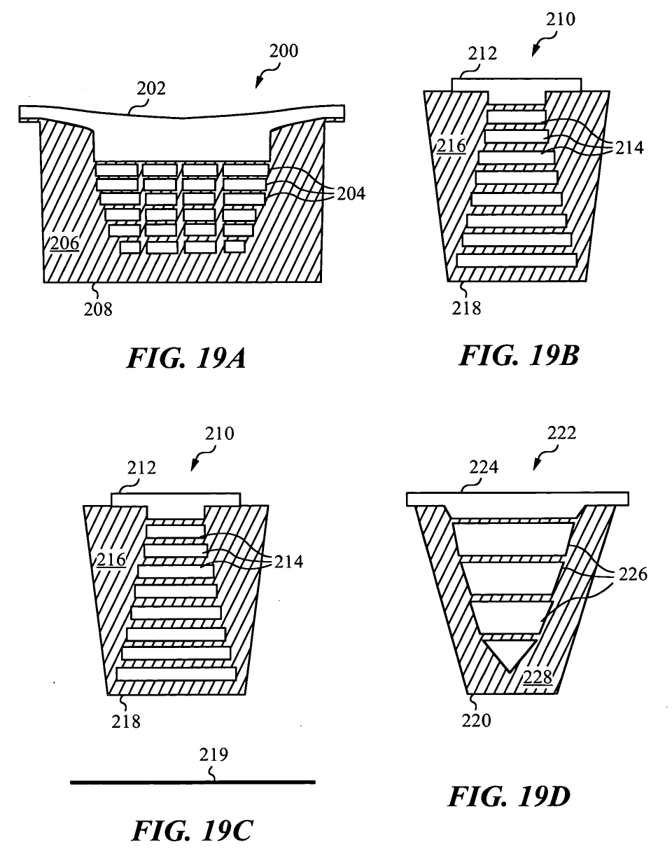

Devices in accordance with the invention can take advantage of series capacitive structures that have various geometries. FIG. 19A illustrates a series capacitive structure 200 that has a top element 202 and floating elements 204 that are interdigitated. More precisely, elements 204 are plate portions potted in an insulating material or dielectric 206 within trench 208. In FIG. 19B a series capacitive structure 210 has a top element 212 and floating elements 214 that are all plate-shaped and potted in a dielectric 216 of trench 218. In contrast to previous embodiments, the top-most plates 214 are smallest and the bottom-most plates 214 are largest.

FIG. 19C illustrates structure 210 of FIG. 19B but in this embodiment trench 218 is not etched all the way through to the n+ substrate 219. Finally, FIG. 19D illustrates a more tapered trench 220 containing a series capacitive structure 222 composed of a top element 224 in the form of a plate and floating elements 226. Elements 224 and 226 are potted in a dielectric 228. All elements 226 are in the form of plates, with the exception of the bottom-most element 224, which is tapered to a point. A person skilled in the art will recognize that various other permutations and geometries can be used in the design of series capacitive structures in accordance with the invention.

As mentioned above, appropriate terminating structure should be employed with semiconductor devices according to the invention. For example, FIG. 18A illustrates device 140 in accordance with the invention terminated by a field plate 146. In another example, shown in FIG. 18B, device 140 has a self-terminating structure in the form of a termination layer 148. Layer 148 can be made of oxide/nitride or other appropriate material known to those familiar with the art. In general terms, a termination structure is electrically coupled to the series capacitive structure for controlling an electric field distribution at the device periphery, thereby obtaining an acceptable breakdown voltage in the termination structure.

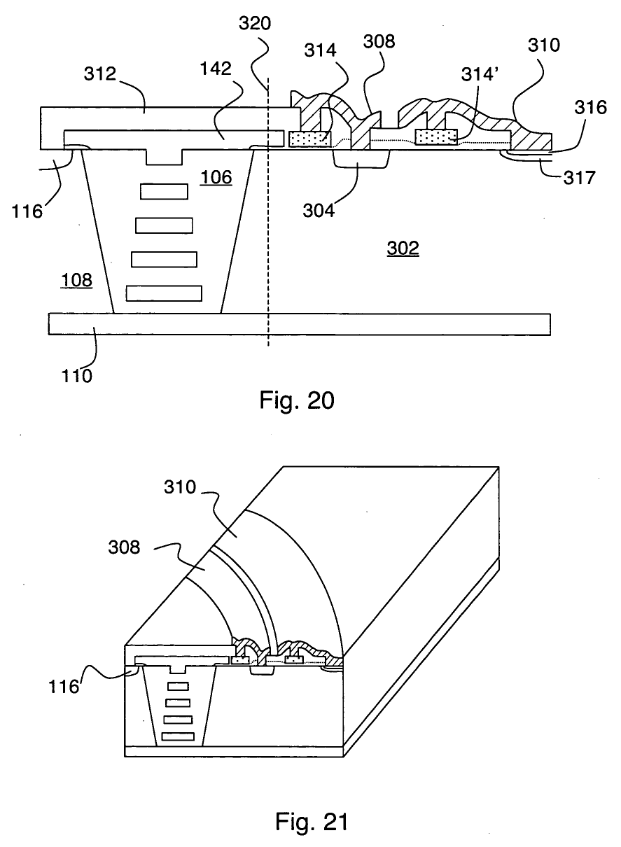

However, the relatively low resistivity of the FCCFET drift region (i.e., intermediate region 22 on FIG. 1 and 108 on FIG. 17), and the presence of vertical floating electrodes can have a substantial effect on implementation of various device termination techniques for FCC devices. For example, FIG. 20 shows an example of capacitive field plate termination applied to an FCCFET. On FIG. 20, line 320 separates the active part of the device (on the left of FIG. 20) from the termination structure (on the right of FIG. 20). A deep p-region 304 forms a PN junction in combination with termination region 302 (which is n-type in this example). A metal line 308 contacts p-region 304 and also makes contact to a first polysilicon region 314. A second metal line 310 contacts a second polysilicon region 314′ and contacts an n+ region 316 in a second p=well 317.

The combination of metal line 308 and polysilicon region 314 acts as a first field plate, and the combination of metal line 310 and polysilicon region 314′ acts as a second field plate. The field plates form a capacitor in parallel with the termination junction, which provides electric field spreading. Polysilicon region 314 is separated from gate 142 such that metal line 308 does not act as a gate contact. Instead, another contact (not shown) serves as the gate contact. Field plates can be fabricated of any conductive material, including but not limited to metals, polysilicon, silicides, conductors, and multi-layer combinations thereof. The field plates are typically disposed on the top surface of the device to enclose the device top region (i.e., p-well 116), e.g., as indicated in the top quarter-section view of FIG. 21. In the example of FIG. 21, metal lines 308 and 310 form concentric rings around top region 116 (as shown). Polysilicon regions 314 and 314′ also form concentric rings around the device top region. Generally, such capacitive field plates need not be circular, nor it is necessary that they be centered on the same point. One or more field plates can be employed.

As the FCCFET is increasingly reverse biased, a depletion region will form in drift region 108, and will extend vertically due to capacitive coupling from the adjacent trench. A termination depletion region will also form, extending vertically and laterally away from p-region 304. Expansion of the termination depletion region laterally can be facilitated by providing additional capacitors in parallel with the termination junction. The doping density in termination region 302 is preferably much less than the doping density of drift region 108, allowing region 302 to be completely depleted without the aid of another trench on the far side of the termination. As a result, the capacitive coupling between the FCC floating elements surrounded by insulator 106 is different on the left side of FIG. 20 (where the doping of drift region 108 is a key parameter) than on the right side of FIG. 20 (where the doping of termination region 302 is a key parameter).

A disadvantage of the capacitive plate technique is that the lateral size of the termination region must be large enough to support the full operating voltage. If the total device area is fixed, increasing the device area devoted to termination decreases the active device area, thereby undesirably increasing the specific on-resistance.

This problem of large lateral termination structure area can be overcome by employing a resistive field plate termination, as shown in the example of FIG. 22. In this approach, a resistive field plate 330 (fabricated, e.g., from semi-insulating polysilicon (SIPOS)) electrically connects to the bottom drain 110. A PN junction is formed by p+ well 326 and n-type termination semiconductor region 322, and is separated from resistive field plate 330 by a termination insulating region 328 (e.g., oxide). This PN-junction includes a metal contact 324. The thickness of insulator 328 is not a critical parameter, and can vary over a wide range (e.g., 0.02 μm to 2 μm). A passivation layer 332 (e.g., nitride) covers field plate 330. Field plate 330 acts as a large resistor (resistivity of SIPOS is about 10⁸ Ωcm) which allows a leakage current to flow responsive to a voltage bias. The potential distribution within field plate 330 is linear, thereby providing the electrical field uniformity in termination region 322 needed for high breakdown voltage.

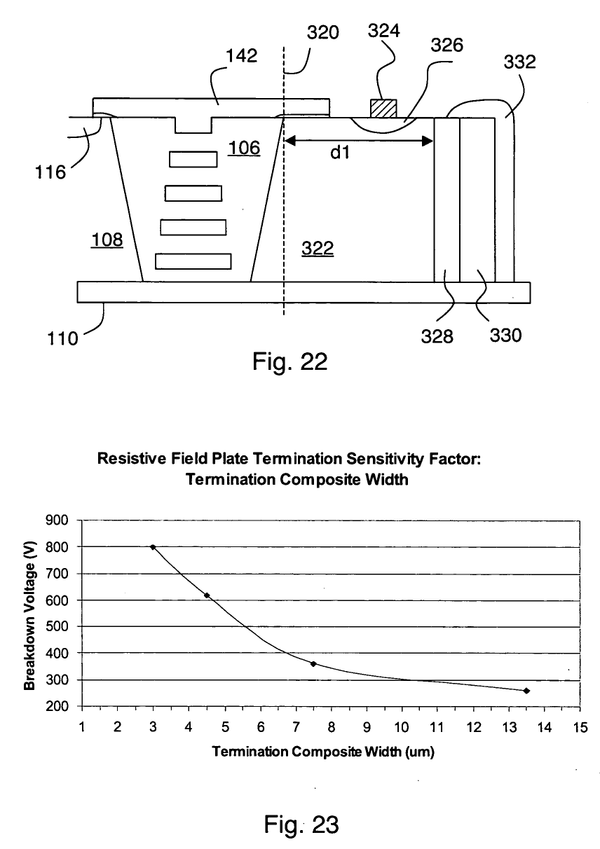

The distance between the FCC trench and insulator 328 of the termination structure (d1 on FIG. 22) is an important design parameter. If this distance is too large, field plate 330 will not be able to provide electric field uniformity throughout termination region 322, thereby leading to a decreased breakdown voltage. Breakdown voltage decreases as d1 increases on the plot of FIG. 23.

Although this approach provides a small-area termination region, it entails the introduction of additional leakage current, which is often undesirable. Furthermore, the large resistance of plate 330 leads to a large RC time constant, thereby degrading the transient performance of this termination approach. Irreversible catastrophic breakdown can occur in response to a transient.

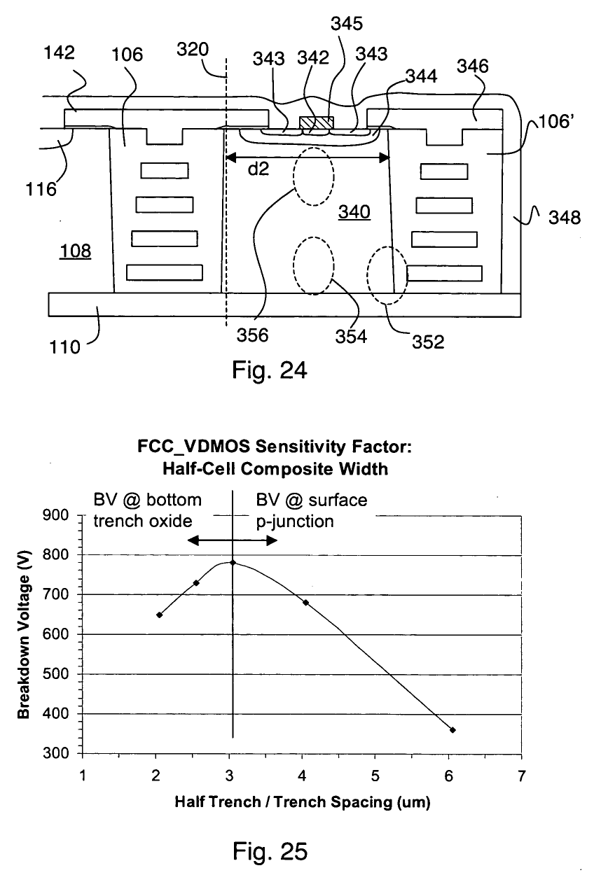

FIG. 24 shows a preferred FCCFET device termination approach. In this approach, a second floating series capacitive structure is employed to terminate the active device. In the example of FIG. 24, a termination semiconductor region 340 is disposed between the active FCC structure having top element 142 and floating elements embedded in insulator 106 and a termination FCC structure having top element 346 and floating elements embedded in an insulator 106′ filling a second trench. The silicon to the right of the termination trench is removed (e.g., with an selective etch that removes silicon without removing insulator 106′), and the termination structure is then passivated with a passivation layer 348. Suitable materials for passivation layer 348 include but are not limited to: oxides, nitrides, doped silicon dioxide, undoped silicon dioxide, silicon nitride, plasma-deposited nitride, silicon carbide, and diamond-like films.

Optionally, a conductive channel may be present in the termination structure. Such a channel can be provided in a well 344 having opposite doping compared to termination region 340 (e.g., if region 340 is n-type, well 344 is p-type). More specifically, one way to provide the channel includes a metal source contact 345 making electrical contact to source 343 and to p+ region 342. With this configuration, top elements 142 and 346 can act as gates to create a conductive channel by the field effect in the parts of p-well 344 immediately below the gates. This channel permits current to flow between source 343 and termination region 340. Having a conductive channel in the termination structure is preferred to minimize total device area.

The preferred termination approach of FIG. 24 can be regarded as a self-termination approach, in the sense that a second FCC structure is employed to terminate an active device including an FCC structure. Such self-termination provides several advantages. More specifically, the lateral area required for termination is reduced, since the operating voltage of the device is terminated vertically instead of laterally. Since significant extra area for termination is not required, the specific on-resistance vs. breakdown performance can be maximized. Furthermore, as described above, FCC structures can respond quickly to voltage transients. Therefore, self-termination with a second FCC structure provides improved transient response compared to the resistive field plate approach of FIG. 22.

For FCC self-termination, it is important to design the device such that the location of initial breakdown in the termination structure is in preferred locations and away from non-preferred locations. More specifically, it is undesirable for breakdown to initiate at an interface between termination region 340 and trench dielectrics 106 or 106′ (e.g., such as location 352), since breakdown at such a location can cause breakdown instability by charge injection to the floating elements. Thus breakdown locations such as 354 and 356 are preferred, since they are away from the trench-termination region interfaces.

FIG. 25 shows a plot of breakdown voltage vs. termination region half-width (i.e., d2/2) on FIG. 24. As shown on this figure, the location where breakdown initiates depends on d2. A combination of a slightly deeper termination junction with d2 slightly larger than the d2 providing maximum breakdown voltage (e.g., slightly to the right of the peak on FIG. 25) is found to reliably provide breakdown at the above-identified preferred locations, thereby improving device reliability and ruggedness.

Individual cells of any of the above-described embodiments may be combined together, with proper terminating structures separating them, into larger devices. Such devices preferably have cells that are adjacent each other. In some embodiments adjacent cells may even share the same series capacitive structure. In this manner, efficient use is made of the series capacitive structure, where integration of several high-voltage devices in the same epi material is made possible.

Many other embodiments of the semiconductor device in accordance with the invention are possible. For example, the above figures and concepts have been illustrated with n-channel devices. P-channel devices can also be constructed in accordance with the invention. Thus, in very general terms, a semiconductor device in accordance with the invention can be used to make various components or portions of components including diodes, photodiodes, transistors, phototransistors, bipolar transistor, MOSFET, IGBT, JFET, thyristor and many others. Therefore, given the wide range of devices enabled by the above description, the scope of the invention should be judged by the appended claims and their legal equivalents.

1. A semiconductor device comprising:
a) a top region, an intermediate region, and a bottom region;
b) a controllable current path traversing any of said regions;
c) a first insulating trench coextensive with and girding said top region and said intermediate region;
d) a first series capacitive structure disposed in said insulating trench and having a biased top element;
wherein said intermediate region has a capacitive property for establishing a capacitive coupling between said first series capacitive structure and said intermediate region, thereby obtaining a high breakdown voltage in said current path; and
e) a termination structure electrically coupled to said first series capacitive structure for controlling an electric field distribution at a periphery of said semiconductor device, thereby obtaining an acceptable breakdown voltage in said termination structure.

2. The device of claim 1, wherein said termination structure comprises a capacitive field plate termination structure having one or more capacitive field plates disposed at a top part of said termination structure.

3. The device of claim 2, wherein a doping density of said termination region is substantially lower than a doping density of said intermediate region.

4. The device of claim 2, wherein said one or more field plates are disposed to enclose said top region of said semiconductor device.

5. The device of claim 2, wherein said capacitive field plates comprise a material selected from the group consisting of: metals, polysilicon, silicides, conductors, and multi-layer combinations thereof.

6. The device of claim 1, wherein said termination structure comprises a resistive field plate termination structure including:
a termination semiconductor region around said insulating trench
a termination insulating region around said termination semiconductor region
a resistive field plate around said termination insulating region, wherein said resistive field plate is electrically connected to said bottom region; and
a PN junction disposed at a top part of said termination semiconductor region, between said insulating trench and said termination insulating region.

7. The device of claim 6, wherein said resistive field plate comprises semi-insulating polysilicon.

8. The device of claim 6, wherein said termination insulating region comprises oxide.

9. The device of claim 6, wherein a thickness of said termination semiconductor region is selected to enhance uniformity of said electric field distribution.

10. The device of claim 1, wherein said termination structure comprises a vertical trench series capacitive termination structure including:
a termination semiconductor region around said first insulating trench;
a second insulating trench around said termination semiconductor region;
a second series capacitive structure disposed in said second insulating trench.

11. The device of claim 10, wherein said termination semiconductor region comprises a conducting channel.

12. The device of claim 10, wherein a passivation layer is disposed on an outward facing surface of said second insulating trench.

13. The device of claim 12, wherein said passivation layer comprises a material selected from the group consisting of oxides, nitrides, doped silicon dioxide, undoped silicon dioxide, silicon nitride, plasma-deposited nitride, silicon carbide, and diamond-like films.

14. The device of claim 10, wherein a thickness of said termination semiconductor region is selected such that a breakdown location within said termination semiconductor region is away from said first insulating trench and is away from said second insulating trench.

15. The device of claim 10, wherein a thickness of said termination semiconductor region is selected such that a breakdown location within said termination semiconductor region is near a top surface of said termination semiconductor region.

16. A method for maximizing the breakdown voltage in a semiconductor device having a top region, an intermediate region and a bottom region and a controllable current path traversing any of said regions, said method comprising:
a) providing a first insulating trench coextensive with and girding said top region and said intermediate region;
b) disposing a first series capacitive structure in said insulating trench;
c) biasing a top element of said series capacitive structure;
d) adjusting a capacitive property of said intermediate region to establish a capacitive coupling between said series capacitive structure and said intermediate region to obtain a high breakdown voltage in said current path; and
e) controlling an electric field distribution at a periphery of said semiconductor device with a termination structure electrically coupled to said first series capacitive structure, thereby obtaining an acceptable breakdown voltage in said termination structure.

17. The method of claim 16, wherein said termination structure comprises a capacitive field plate termination structure having one or more capacitive field plates disposed on top of a termination region.

18. The method of claim 16, wherein said termination structure comprises a resistive field plate termination structure including:
a termination semiconductor region around said insulating trench
a termination insulating region around said termination semiconductor region
a resistive field plate around said termination insulating region, wherein said resistive field plate is electrically connected to said bottom region; and
a PN junction disposed at a top part of said termination semiconductor region, between said insulating trench and said termination insulating region.

19. The method of claim 16, wherein said termination structure comprises a vertical trench series capacitive termination structure including:
a termination semiconductor region around said first insulating trench;
a second insulating trench around said termination semiconductor region;
a second series capacitive structure disposed in said second insulating trench.

20. A semiconductor device having cells, each of said cells comprising:
a) a top region, an intermediate region and a bottom region;
b) a controllable current path traversing any of said regions;
c) an insulating trench coextensive with and girding said top region and said intermediate region;
d) a series capacitive structure disposed in said insulating trench and having a biased tip conductor;
said intermediate region having a capacitive property establishing a capacitive coupling between said series capacitive structure and said intermediate region, thereby obtaining a high breakdown voltage in said current path; and
e) a termination structure electrically coupled to said series capacitive structure for controlling an electric field distribution at a periphery of said semiconductor device, thereby obtaining an acceptable breakdown voltage in said termination structure.
